(19) United States
(12) Patent Application Publication
(10) Pub. No.: US 2023/0225080 A1
(43) Pub. Date: Jul. 13, 2023

(54) HYBRID HEATSINK SYSTEM

(71) Applicant: Arista Networks, Inc., Santa Clara, CA (US)

(72) Inventors: Ernest THURLOW, Mountain View, CA (US); Tiffany DORIA, Fremont, CA (US)

(21) Appl. No.: 17/574,318

(22) Filed: Jan. 12, 2022

(51) Int. Cl. H05K 7/20

(52) U.S. Cl. CPC H05K 7/20309; H05K 7/20336; H05K 7/20318

(57) ABSTRACT

A passive hybrid heat transfer system for cooling a heat source, such as an integrated circuit, includes a thermosiphon heat transfer subsystem that operates in combination with a supplemental heat transfer subsystem to transfer heat away from and thereby cool the integrated circuit. The heat transfer system includes the thermosiphon heat transfer subsystem including a condenser coupled to an evaporator. The evaporator is coupled to the integrated circuit or other heat source and is positioned below the condenser relative to a direction of gravity. The supplemental heat transfer subsystem is thermally coupled to the evaporator of the thermosiphon heat transfer subsystem and has at least a portion extending below the evaporator relative to the direction of gravity. A network device like a switch or router may include the hybrid heat transfer system to cool high power integrated circuits without the need to resort to active cooling systems.

### BACKGROUND

Integrated circuits contained within electronic devices, such as application specific circuits (ASICs), include ever-increasing numbers of transistors operating at ever-increasing frequencies. As a result, the power consumed by these integrated circuits increases accordingly, along with heat generated by the integrated circuits due to this increased power consumption. Heat transfer systems must accordingly be included in the electronic devices to transfer heat generated by these integrated circuits and maintain appropriate operating temperatures within the electronic device during operation. Various types of passive heat transfer technologies, which transfer heat away from the integrated circuit or other heat source, are commonly utilized to cool integrated circuits. These heat transfer technologies include thermosiphon systems, heat pipe systems, and vapor chamber systems. Each type of heat transfer system or heatsink has limitations as to the maximum amount of heat that may be transferred away from the integrated circuit.

As the power consumed by integrated circuits continues to increase, it is becoming increasingly more difficult to adequately cool integrated circuits using passive heat transfer technologies. Fluid heat transfer systems can transfer more heat than these types of passive heat transfer technologies and thus may be utilized instead to cool high-power integrated circuits. Fluid heat transfer systems are, however, typically more costly to manufacture and maintain and may increase power consumption of the electronic device, as well as increase risks in the event of a failure. Other active heat transfer or cooling systems utilizing fans or other air transfer devices may also be utilized to cool integrated circuits. Undesirably, these types of active cooling systems also will increase the power consumption of the electronic device including the integrated circuits.

There is a need for improved passive heat transfer techniques for cooling heat sources such as integrated circuits including ever-increasing numbers of transistors operating at ever-increasing frequencies.

### BRIEF DESCRIPTION OF THE DRAWINGS

With respect to the discussion to follow and in particular to the drawings, it is stressed that the particulars shown represent examples for purposes of illustrative discussion and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, makes apparent to those of skill in the art how embodiments in accordance with the present disclosure may be practiced. Similar or same reference numbers may be used to identify or otherwise refer to similar or same elements in the various drawings and supporting descriptions.

FIG. 1 illustrates a hybrid heat transfer system including a thermosiphon heat transfer subsystem having an evaporator and a supplemental heat transfer subsystem positioned below the evaporator relative to a direction of gravity according to an embodiment of the present disclosure;

FIG. 2 illustrates a hybrid heat transfer system including a thermosiphon heat transfer subsystem having an evaporator and a supplemental heat transfer subsystem positioned entirely below the evaporator according to another embodiment;

FIG. 3 illustrates a hybrid heat transfer system including a thermosiphon heat transfer subsystem having an evaporator and a supplemental heat transfer having a portion positioned below the evaporator according to another embodiment;

FIG. 4 illustrates a hybrid heat transfer system including a thermosiphon heat transfer subsystem having an evaporator and a supplemental heat transfer subsystem with a portion positioned below the evaporator according to a further embodiment;

FIG. 5A is an exploded perspective view illustrating the physical structure of a hybrid heat transfer system including a thermosiphon heat transfer subsystem and supplemental heat transfer subsystem according to another embodiment of the present disclosure;

FIG. 5B is a perspective view of the assembled hybrid heat transfer system of FIG. 5A; and

FIG. 6 is a functional block diagram of a network device including a control plane having an application specific circuit coupled to a hybrid heat transfer system according to another embodiment of the present disclosure.

### DETAILED DESCRIPTION

Described in the present application are structures and techniques for passive hybrid heat transfer systems that improve the heat transfer capabilities of the system for better cooling heat sources such as integrated circuits in network devices. In the following description, for purposes of explanation, numerous examples and specific details are set forth in order to provide a thorough understanding of some embodiments. Some embodiments as defined by the claims may include some or all of the features in these examples alone or in combination with other features described below and may further include modifications and equivalents of the features and concepts described herein.

In embodiments of the present disclosure, a passive hybrid heat transfer system utilizes a thermosiphon heat transfer subsystem and a supplemental heat transfer subsystem that work in combination to transfer sufficient heat away from a heat source and thereby adequately cool the integrated circuit or other heat source. The supplemental heat transfer subsystem may, for example, be a heat pipe or vapor chamber heat transfer subsystem. The supplemental heat transfer subsystem is located in space around the thermosiphon heat transfer subsystem that is typically not utilized due to the physical constraints of a thermosiphon heat transfer subsystem. In a thermosiphon heat transfer subsystem, an evaporator is thermally coupled to a heat source and includes a condenser thermally coupled to the evaporator. The evaporator must be positioned below the condenser so that fluid in the condenser returns to the evaporator due to the force of gravity. As a result, the space under the evaporator relative to the direction of gravity may be unused or wasted in a thermosiphon heat transfer subsystem. Hybrid heat transfer systems according to some embodiments of the present disclosure utilize this space below the evaporator of a thermosiphon heat transfer subsystem by locating at least a portion of the supplemental heat transfer subsystem in this space. The supplemental heat transfer subsystem is thermally coupled to either the evaporator or the heat source and may include a portion extending below the evaporator relative to the direction of gravity. This enables the supplemental heat transfer subsystem to transfer additional heat away from the heat source. In operation, the thermosiphon heat transfer subsystem and supplemental heat transfer subsystem operate together to transfer sufficient heat away from the heat source to adequately cool the heat source during its operation.

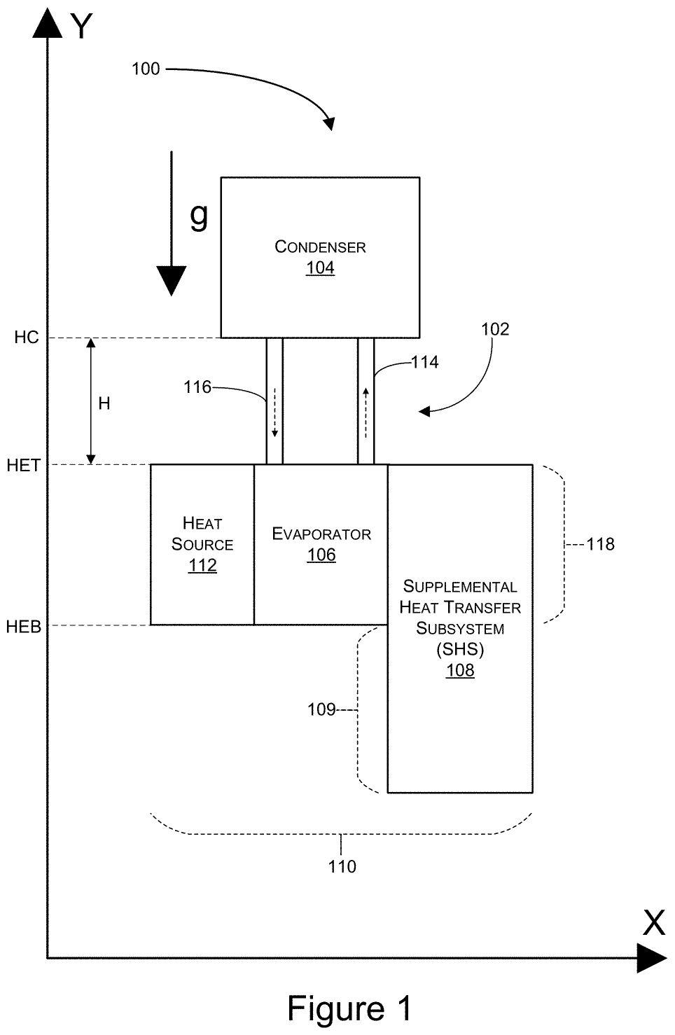

FIG. 1 illustrates a hybrid heat transfer system 100 including a thermosiphon heat transfer subsystem 102 having a condenser 104 and an evaporator 106 and further including a supplemental heat transfer subsystem (SHS) 108 with at least a heat dissipation portion 109 positioned in a space 110 below the evaporator relative to a direction of gravity g according to an embodiment of the present disclosure. In this way, hybrid heat transfer system 100 includes the SHS 108 to increase the heat transfer capacity and thereby improve the cooling of a heat source 112 coupled to the hybrid heat transfer system. Heat source 112 may be an integrated circuit, such as an application specific integrated circuit (ASIC), a processor, or any other type of electronic component or other non-electronic component. More generally, heat source 112 may be any electronic component or non-electronic component that generates sufficient heat during operation to require dissipation of the heat in order to maintain the temperature of the component within a specified operating temperature range during operation.

SHS 108 may be any of a variety of different types of passive heat transfer technologies such as a heat pipe heat transfer subsystem, a vapor chamber heat transfer subsystem, or any passive heat sink subsystem having a structure configured to maximize a surface area of the structure in contact with a surrounding cooling medium. The location or position of SHS 108 takes advantage of normally unused space 110 below evaporator 106 of thermosiphon heat transfer subsystem 102. This space 110 is normally unused due to the way in which thermosiphon heat transfer subsystem 102 operates in relying on gravity g to return a condensed fluid in condenser 104 to evaporator 106, as will be described in more detail below. One skilled in the art will understand suitable materials such as aluminum, copper, and other thermally conductive materials to form the SHS 108.

The operation and structure of thermosiphon heat transfer subsystem 102 will now be described in more detail to better understand advantages of the structure of hybrid heat transfer system 100. One skilled in the art will understand the operating principles and physical structure of thermosiphon systems, and thus these principles and structures will only be described to the extent necessary to enable one skilled in the art to understand the structure and advantages of hybrid heat transfer system 100. Thermosiphon heat transfer subsystem 102 contains a suitable working fluid such as water, ethanol, refrigerants (e.g., R134), or methanol, for example, with the specific working fluid being chosen based on the required temperatures at which the thermosiphon system must operate. One skilled in the art will understand suitable materials, such as aluminum, copper, and other thermally conductive materials, to form the components of thermosiphon heat transfer subsystem 102.

In operation, heat from heat source 112 is supplied to evaporator 106 and in response to this heat, the working fluid in the evaporator is vaporized and exits the top of the evaporator through vapor tube 114. The vaporized working fluid exits evaporator 106 and travels upward through vapor tube 114 to condenser 104. The upward dashed arrow in vapor tube 114 in FIG. 1 indicates this upward movement or travel of the vaporized working fluid from evaporator 108 and through the vapor tube to condenser 104. In condenser 104, heat is removed from the vaporized working fluid and the vaporized working fluid condenses to a liquid. The liquidized working fluid in condenser 104 then flows or drains, under the force of gravity g, through fluid return tube 116 and back to evaporator 106. This travel of the liquidized working fluid downward through fluid return tube 116 is indicated through the downward dashed arrow in fluid return tube 116 in FIG. 1.

Because thermosiphon heat transfer subsystem 102 relies on the force of gravity g to return the liquidized working fluid in condenser 104 to evaporator 106 via the fluid return tube 116, the condenser must be positioned above the evaporator relative to the direction of gravity. In FIG. 1, an X-axis and a Y-axis are illustrated. The force of gravity g is parallel to the Y-axis in this example embodiment, but in other embodiments, the force of gravity may be at an angle to the Y-axis (such as between −90° and 90° of the illustrated angle) provided only that the angle allows sufficient gravitational force to act such that the condenser and evaporator operate effectively. Evaporator 106 is positioned below condenser 104 relative to the direction of gravity g, namely along a direction parallel to the Y-axis. In the example of FIG. 1, condenser 104 is at a height HC that is higher by a height H than a height HET of the top of evaporator 106. In the example of FIG. 1, a top surface of evaporator 106 is at the height HET while a bottom surface of the evaporator is at a height HEB Evaporator 106 accordingly has a thickness or height along the direction parallel to the Y-axis equal to (HET-HEB). Space 110 corresponds to the volume or region which is underneath, relative to the direction of gravity g, the bottom surface of evaporator 106 at height HEB

Due to the reliance on the force of gravity g in thermosiphon systems such as the thermosiphon heat transfer subsystem 102, space 110 below evaporator 106 in the direction of the force of gravity g (i.e., along the direction of gravity g or parallel to the Y-axis) is not utilized by the thermosiphon heat transfer subsystem. This is true because if any portion of fluid return tube 116 were to be positioned below evaporator 106, then thermosiphon heat transfer subsystem 102 would need to include some means of returning the liquidized working fluid in this portion of the fluid return tube upward against the force of gravity g to the evaporator.

In hybrid heat transfer system 100, SHS 108 includes heat dissipation portion 109 that extends into space 110 not utilized by thermosiphon heat transfer subsystem 102. In this way, SHS 108 utilizes this unused space and also provides additional heat transfer capacity for hybrid heat transfer system 100 to help transfer heat away from and thereby help cool heat source 112. In the example embodiment of FIG. 1, heat source 112 is physically attached to a first surface of evaporator 106 that is opposite a second surface of the evaporator. Attachment portion 118 of SHS 108 is physically attached to the second surface of evaporator 106, with heat dissipation portion 109 of the SHS extending below the attachment portion relative to the direction of gravity g. Heat source 112 and SHS 108 are physically attached to evaporator 106 and in this way thermally coupled to the evaporator. The manner in which each of heat source 112 and SHS 108 is attached to evaporator 106 may vary in different embodiments of the present disclosure. For example, heat source 112 may be attached to evaporator 106 through screws and bolts while SHS 108 is attached through brazing. Any suitable attachment technique or device may be used to attach each of heat source 112 and SHS 108 to evaporator 106. A permanent attachment technique such as brazing is typically utilized to attach SHS 108 and evaporator 106 to thereby form hybrid heat transfer system 100. Thereafter, a removable attachment technique such as screws and bolts would be utilized to attach heat source 112 to hybrid heat transfer system 100.

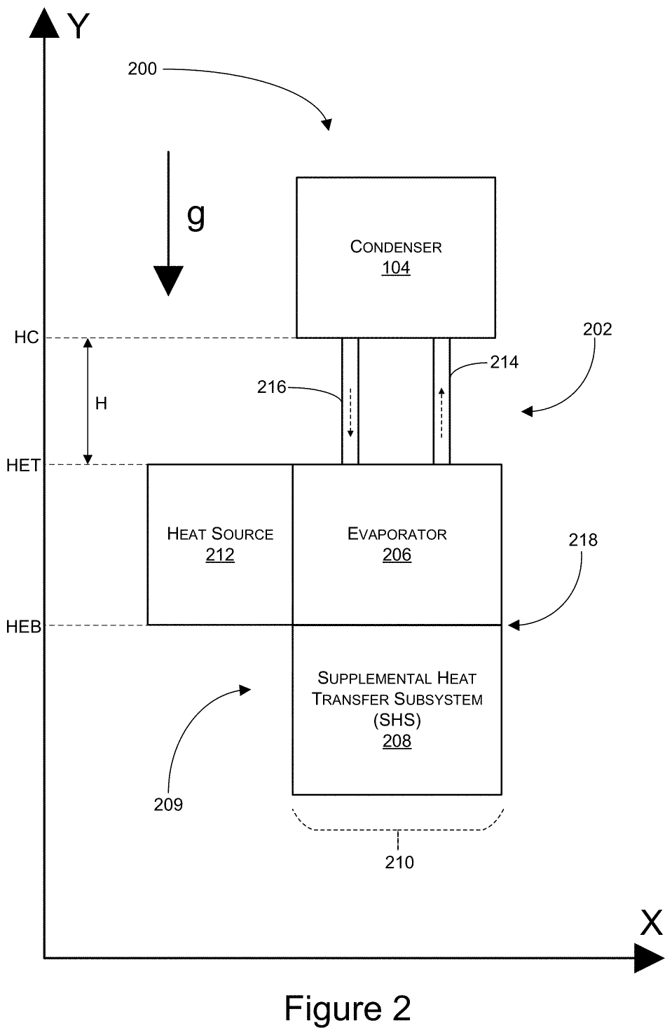

Heat source 112, SHS 108 and evaporator 108 may be attached in different arrangements or configurations so long as at least a portion 109 of SHS 108 is positioned in space 110 below the evaporator. In the example embodiment of FIG. 1, SHS 108 is attached to a surface of evaporator 106 opposite the surface to which heat source 112 is attached. Different coupling configurations of SHS 108 and heat source 112 to evaporator 106 will be described in more detail below with reference to FIGS. 2-4. As will be understood by those skilled in the art, the physical attachment of SHS 108 and heat source 112 to the evaporator 106 also thermally couples these components together, enabling each of SHS and evaporator 106 to transfer heat away from and thereby cool the heat source. Thus, in the present description SHS 108 and heat source 112 may be described as being “attached to” or “thermally coupled” to evaporator 106, and these terms may be used interchangeably when describing these components and the thermal coupling among the components.

FIG. 2 illustrates a hybrid heat transfer system 200 according to another embodiment of the present disclosure. In hybrid heat transfer system 200, the functionality and operation of components 202-218 correspond to the functionality and operation of components 102-118 of FIG. 1 and will accordingly not again be described in detail. Hybrid heat transfer system 200 includes thermosiphon heat transfer subsystem 202 having condenser 204 and evaporator 206 and includes SHS 208 positioned entirely below the evaporator according to another embodiment. Evaporator 206, SHS 208 and heat source 212 accordingly have a different configuration in the embodiment of FIG. 2, with the entire SHS 208 being located or positioned in space 210 under evaporator 206 relative to or along the direction of gravity g.

In hybrid heat transfer system 200, evaporator 206 includes a lower surface to which the attachment portion 218 of SHS 208 is attached. Thus, the entire SHS 208 is positioned under or extends below evaporator 206 relative to the direction of gravity g, which is shown parallel to the Y axis. Both attachment portion 218 and heat dissipation portion 209 of SHS 208 are positioned below evaporator 206 along the direction of gravity g in hybrid heat transfer system 200. SHS 208 is in this way thermally coupled to evaporator 206 and operates in combination with the evaporator of thermosiphon heat transfer subsystem 202 to transfer heat away from and thereby cool heat source 212.

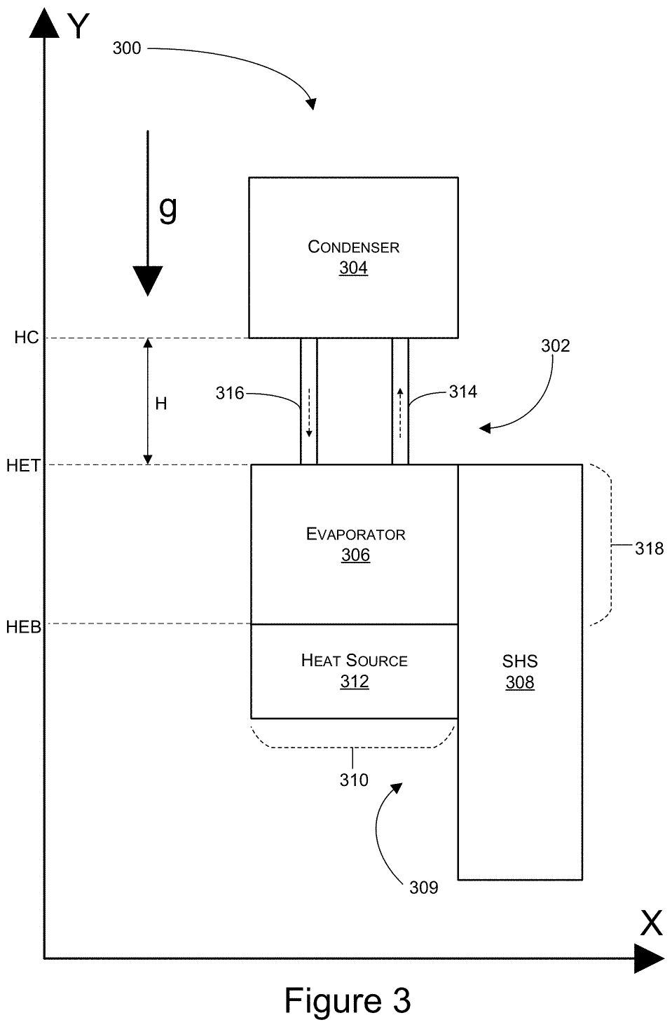

FIG. 3 illustrates yet another example of a hybrid heat transfer system 300 according to another embodiment of the present disclosure. In hybrid heat transfer system 300, the functionality and operation of the components 302-318 correspond to the functionality and operation of the components 102-118 of FIG. 1 and will accordingly not again be described in detail. Hybrid heat transfer system 300 includes SHS 308 that is directly attached to both evaporator 306 and heat source 312. Once again, SHS 308 and evaporator 306 of the thermosiphon heat transfer subsystem 302 operate in combination to transfer heat away from and thereby cool heat source 312. In this embodiment, attachment portion 318 of SHS 308 is illustrated as corresponding to the portion of SHS attached to evaporator 306, with heat dissipation portion 309 of the SHS corresponding to the portion extending below the evaporator (i.e., under the height HEB) relative to the direction of gravity g. Attachment portion 318 of SHS may alternatively be viewed as the portion of SHS attached to both evaporator 306 and a heat source 312 in this embodiment.

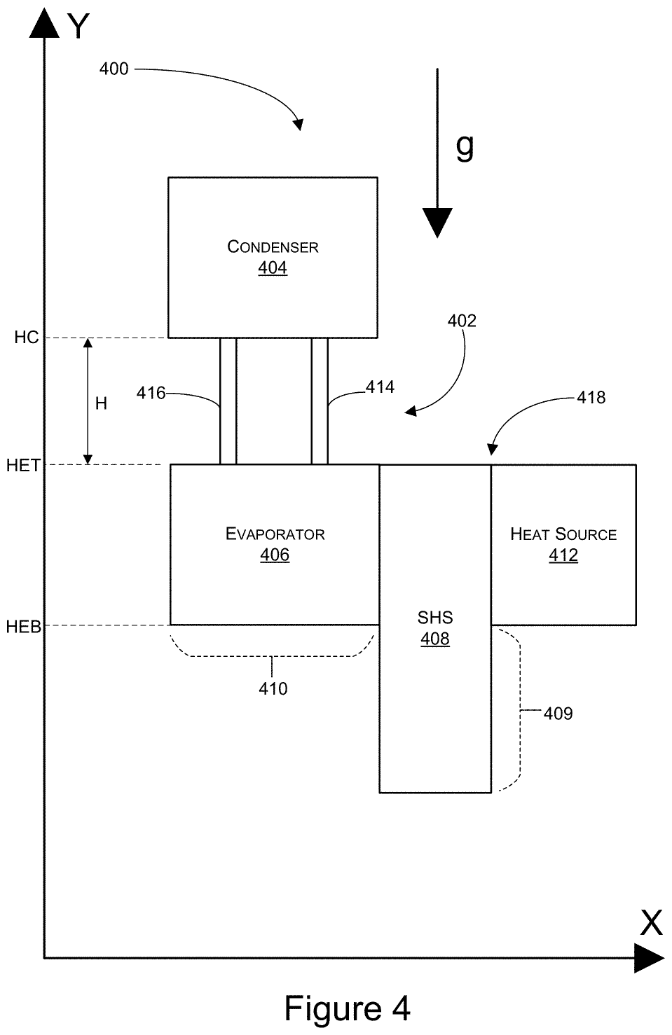

FIG. 4 illustrates yet another example of a hybrid heat transfer system 400 according to a further embodiment of the present disclosure. In hybrid heat transfer system 400, the functionality and operation of the components 402-418 correspond to the functionality and operation of the components 102-118 of FIG. 1 and will accordingly not again be described in detail. In hybrid heat transfer system 400, SHS 408 is coupled between evaporator 406 and heat source 412 in a further possible configuration of these components. In this way, evaporator 406 is thermally coupled through attachment portion 418 of SHS 408 to heat source 412. SHS 408 and evaporator 406 of the thermosiphon heat transfer subsystem 402 operate in combination to transfer heat away from and thereby cool heat source 412.

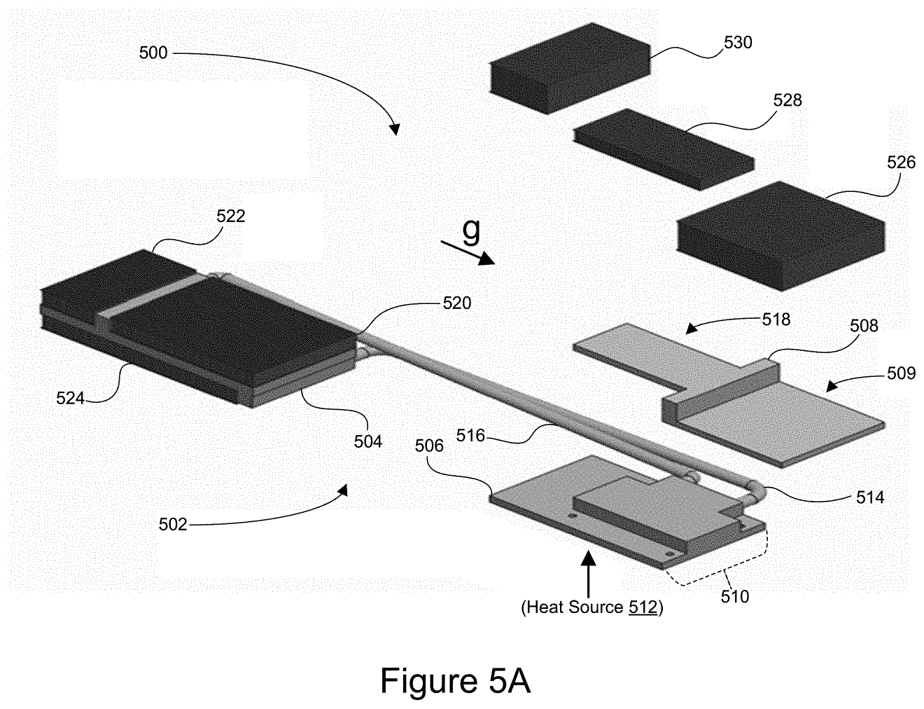

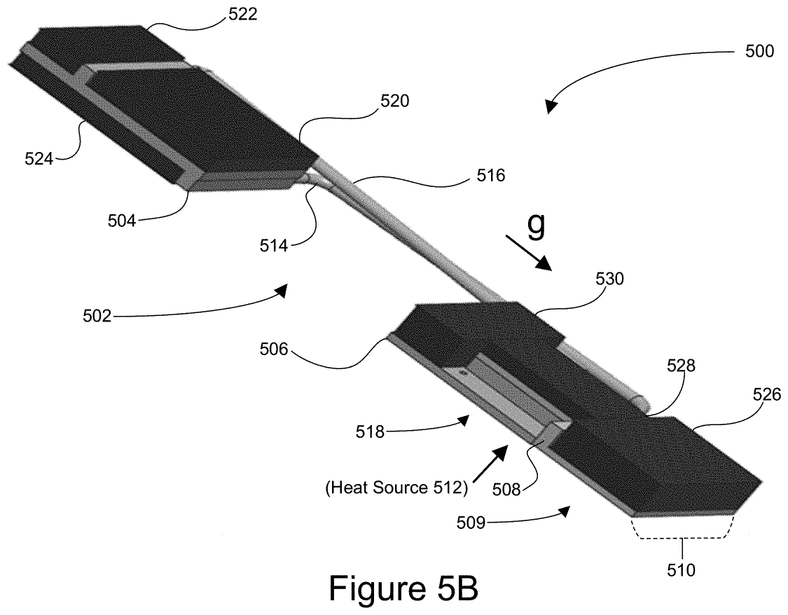

FIG. 5A is an exploded perspective view illustrating the physical structure of a hybrid heat transfer system 500 according to another embodiment of the present disclosure. Hybrid heat transfer system 500 includes a thermosiphon heat transfer subsystem 502 having a condenser 504 and an evaporator 506 and further includes a supplemental heat transfer subsystem (SHS) 508 having a heat dissipation portion 509 extending in a space 510 below the evaporator relative to the direction of gravity g. SHS 508 is a vapor chamber type of heat transfer subsystem in the embodiment of FIG. 5A. Heat source 512 (not expressly shown) would be attached to a lower side surface of the evaporator 506 in the orientation of FIG. 5A, as illustrated by the arrow in the figure. A vapor tube 514 and a fluid return tube 516 interconnect the condenser 504 and evaporator 506. SHS 508 includes an attachment portion 518 that is configured to be attached to an upper side surface of the evaporator 506 in the orientation of FIG. 5A. The attachment portion 518 would be attached to the evaporator 506 through a suitable attachment technique such as brazing, or through alternative devices such as screws or clamps, or through any other suitable attachment device or technique. In addition, the structure of SHS 508 has a shape to accommodate the structure of the evaporator 506. SHS 508 has to be shaped, for example, to not interfere with the vapor tube 514 and fluid return tube 516 extending between the evaporator 506 and condenser 504.

In operation of the vapor chamber device 508, the vapor chamber device includes a hot interface (attachment portion 518) at which the vapor chamber is thermally coupled to evaporator 506 causing a fluid in the heat pipe to absorb heat from a thermally conductive solid surface of the heat pipe and to turn into a vapor. This vapor travels through the vapor chamber device 508 to a cold interface (dissipation portion 509) of the vapor chamber and condenses back into a liquid, releasing the latent heat and in this way removing heat from evaporator 506. The condensed liquid at the cold interface (dissipation portion 509) then returns through capillary action against the force of gravity g to the hot interface (attachment portion 518). In this way, vapor chamber device 508 helps cool evaporator 506 and thereby heat source 512.

Hybrid heat transfer system 500 further includes a plurality of heat sinks 520, 522, and 524 configured to be attached to the upper side surface of condenser 504 of thermosiphon heat transfer subsystem 502. Each heat sink 520-524 is formed from a suitable thermally conductive material or materials, such as aluminum and copper, and has a structure to dissipate heat from condenser 504 generated during operation of thermosiphon heat transfer subsystem 502. For example, each heat sink 520-524 may include a base configured to be attached to condenser 504 and having a plurality of fins extending from the base. This type of structure increases the surface area of heat sinks 520-524 to thereby increase heat dissipating capacity, as will be appreciated by those skilled in the art. Similarly, a plurality of heat sinks 526-530 are configured to be attached to the upper side surfaces of SHS 508 and evaporator 506. More specifically, heat sinks 526 and 528 are attached to the upper side surface of SHS 508 while heat sink 530 is attached to a portion of the upper side surface of evaporator 506 that is not covered by attachment portion 518 of SHS 508. Each heat sink 526-530 is also formed from a suitable thermally conductive material and has a suitable structure to dissipate heat from SHS 508 and the evaporator 506.

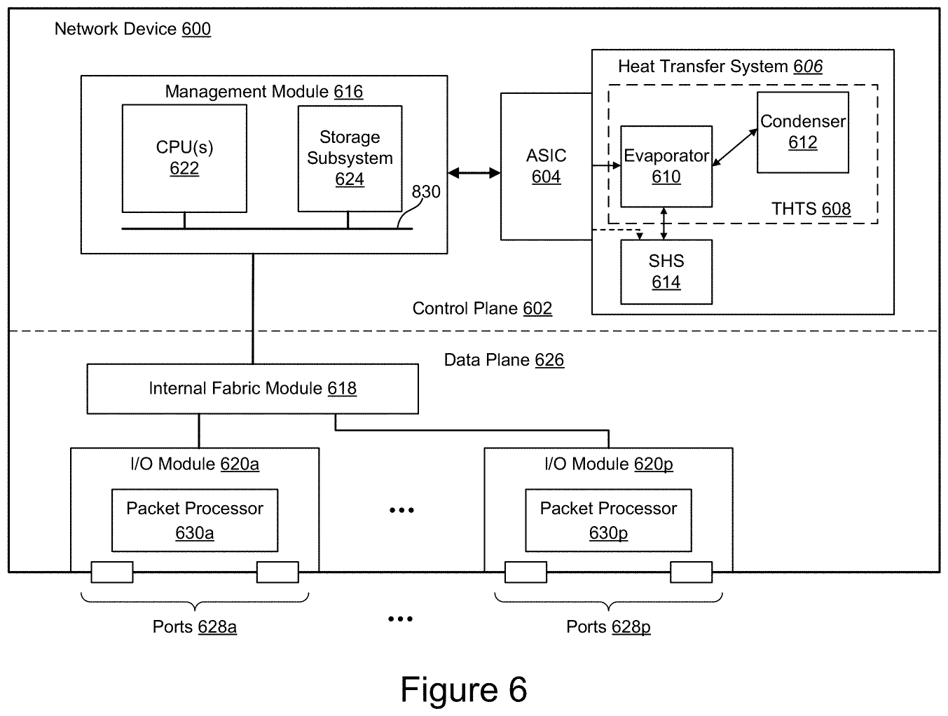

FIG. 5B is a perspective view of the assembled hybrid heat transfer system 500 of FIG. 5A. As seen in FIG. 6, heat sinks 520 and 522 are attached on the upper side surface of the condenser 504 while heat sink 524 is attached to the lower side surface of the condenser. Heat sinks 526 and 528 are attached to the upper side surface of SHS 508 while heat sink 530 is attached to the upper side surface of evaporator 506. Heat dissipation portion 509 of the SHS 508 extends or is positioned in the space 510 below evaporator 506 along or relative to the direction of gravity g as seen in FIG. 5B.

FIG. 6 is a functional block diagram of a network device 600 including control plane 602 having application specific integrated circuit (ASIC) 604 coupled to hybrid heat transfer system 606 according to another embodiment of the present disclosure. Hybrid heat transfer system 606 corresponds to any embodiment of the present disclosure, such as the hybrid heat transfer systems 100-500 of FIGS. 1-5. The hybrid heat transfer system 606 includes a thermosiphon heat transfer subsystem (THTS) 608 having an evaporator 610 that is attached and thereby thermally coupled to the ASIC 604. A condenser 612 is coupled to the evaporator 610 in the THTS 608 and is positioned above the evaporator 610 relative to the direction of gravity as required in a thermosiphon system, which was discussed in more detail above in relation to the embodiments of FIGS. 1-5. A supplemental heat transfer subsystem (SHS) 614 is attached to and thermally coupled to evaporator 610. The SHS 614 may alternatively be coupled to ASIC 604 as illustrated by the dashed line in FIG. 6. In operation of network device 600, THTS 608 and SHS 614 operate in combination to transfer heat away from (and thereby cool) ASIC 604 as described above with reference to the embodiments of FIGS. 1-5.

Network device 600 is a switch or a router, for example, and may also be another type of network device in further embodiments of the present disclosure. Network device 600 includes management module 616, internal fabric module 618, and a number of I/O modules 620a-620p. Management module 616 may be a part of control plane 602, which may also be referred to as control layer, of network device 600 and can include one or more management CPUs 622 for managing and controlling operation of network device 600. Each management CPU 622 can be a general-purpose processor, such as an Intel®/AMD® x86-64 or ARM® processor, operating under the control of software stored in memory, such as storage subsystem 624, which may include read-only memory and/or random access memory.

In some embodiments, CPU 622 may include control circuitry, and may include or be coupled to a non-transitory storage medium storing encoded instructions that cause the CPU to perform desired operations during operation of network device 600. In some embodiments, the non-transitory storage medium may include encoded logic or hardwired logic for controlling operation of CPU 622. Control plane 602 refers to all the functions and processes that determine paths to be used, such as routing protocols, spanning tree, and the like, during operation of the network device 600. Management module 616 and ASIC in control plane 602 include the functional components needed to manage traffic forwarding features of network packets being received by the network device 600. These forwarding features would typically include routing protocols, configuration information and other similar functions that determine the destinations of network packets based on information other than the information contained within these network packets.

Internal fabric module 618 and I/O modules 620a-620p collectively represent a data plane 626 of the network device 600, with the data plane also commonly being referred to as a data layer or a forwarding plane. Data plane 626 is configured by control plane 602 and includes all the functional components needed to perform forwarding operations for network packets received via I/O modules 620a-620p on ingress ports and outputting these network packets via I/O modules on egress ports. Internal fabric module 618 is configured to interconnect I/O modules 620a-620p of network device 600. Each I/O module 620a-620p includes one or more input/output ports 628a-628p that are used by network device 800 to send and receive network packets over communication links (not shown) coupled to the ports. Each I/O module 620a-620p may also include a packet processor 630a-630p. Each packet processor 630a-630p may include forwarding hardware circuitry configured to make wire speed decisions on the processing of incoming (ingress) and outgoing (egress) network packets being communicated over communication links (not shown) coupled to ports 628a-628p. In some embodiments, the forwarding hardware circuitry may include an application specific integrated circuit (ASIC), a field programmable array (FPGA), a digital processing unit, or other suitable structures of configured logic.

The drawings are representative and suggestive of geometries in various described embodiments of hybrid heat transfer systems according to the present disclosure but are not necessarily to scale. The specific shapes of the various components forming hybrid heat transfer systems according to embodiments of the present disclosure may vary in alternative embodiments. Moreover, the specific orientations of any of the described embodiments of hybrid heat transfer systems of FIGS. 1-5 relative to the direction of gravity g may also vary so long as the force of gravity is oriented relative to the condenser and evaporator of the thermosiphon heat transfer subsystem to enable proper operation of this subsystem. Where the supplemental heat transfer subsystem is a heat pipe or vapor chamber heat transfer subsystem, for example, the specific orientation of the supplemental heat transfer subsystem is independent of the direction of the force of gravity g due to the nature of operation of this type of subsystem.

### Further Examples

In various embodiments, the present disclosure includes systems and methods of hybrid passive heat transfer and network devices including hybrid passive heat transfer systems.

In one embodiment, a hybrid heat transfer system, comprises: a thermosiphon heat transfer subsystem including a condenser coupled to an evaporator, the evaporator configured to be coupled to a heat source and positioned below the condenser relative to a direction of gravity; and a supplemental heat transfer subsystem thermally coupled to the evaporator of the thermosiphon heat transfer subsystem, the supplemental heat transfer subsystem including at least a portion extending below the evaporator relative to the direction of gravity.

In an embodiment of the hybrid heat transfer system, the supplemental heat transfer subsystem comprises a heat pipe heat transfer subsystem.

In an embodiment of the hybrid heat transfer system, the supplemental heat transfer subsystem comprises a vapor chamber heat transfer subsystem.

In an embodiment of the hybrid heat transfer system, the evaporator includes a first surface configured to be attached to the heat source and includes a second surface opposite the first surface attached to the supplemental heat transfer subsystem.

In an embodiment of the hybrid heat transfer system, the evaporator is thermally coupled through the supplemental heat transfer subsystem to a heat source.

In an embodiment of the hybrid heat transfer system, the supplemental heat transfer subsystem includes an attachment portion thermally coupled to the first surface of the evaporator and includes a heat dissipation portion extending below the attachment portion and the evaporator relative to the direction of gravity.

In an embodiment of the hybrid heat transfer system, the evaporator includes a lower surface configured to be coupled to the supplemental heat transfer subsystem extending entirely below the evaporator relative to the direction of gravity.

In an embodiment of the hybrid heat transfer system, the condenser of the thermosiphon heat transfer subsystem further comprises heat fins to dissipate heat.

In an embodiment of the hybrid heat transfer system, the supplemental heat transfer subsystem further comprises heat fins to dissipate heat.

In a further embodiment, a hybrid heat transfer system, comprises: a thermosiphon heat transfer subsystem including a condenser coupled to an evaporator, the evaporator having a structure to be coupled to a heat source and being positioned below the condenser along a direction of gravity; and a supplemental heat transfer subsystem thermally coupled to the evaporator of the thermosiphon heat transfer subsystem to remove heat generated by the heat source, at least a portion of the supplemental heat transfer subsystem positioned below the evaporator along the direction of gravity.

In an embodiment of the hybrid heat transfer system, the supplemental heat transfer subsystem comprises at least one of a heat pipe heat transfer subsystem or a vapor chamber heat transfer subsystem.

In an embodiment of the hybrid heat transfer system, the evaporator includes a first surface to be attached to the heat source and includes a second surface opposite the first surface attached to the supplemental heat transfer subsystem.

In an embodiment of the hybrid heat transfer system, the supplemental heat transfer subsystem includes an attachment portion and a heat dissipation portion, the attachment portion including a first surface attached to the evaporator and including a second surface opposite the first surface to be attached to the heat source.

In an embodiment of the hybrid heat transfer system, the evaporator includes a lower surface relative to the direction of gravity and wherein the supplemental heat transfer subsystem is attached to the lower surface and is positioned entirely below the evaporator relative to the direction of gravity.

In an embodiment of the hybrid heat transfer system, the condenser includes a first surface and wherein thermosiphon heat transfer subsystem further comprises at least one heat sink attached to the first surface of the condenser.

In an embodiment of the hybrid heat transfer system, the condenser further includes a second surface opposite the first surface, and wherein the thermosiphon heat transfer subsystem further comprises at least one heat sink attached to the second surface of the condenser.

In an embodiment, the hybrid heat transfer system further comprises at least one heat sink attached to the thermosiphon heat transfer subsystem.

In yet another embodiment, a network device, comprises: a data plane to forward network packets from an ingress port to an egress port; a control plane to configure the data plane, the control plane including: an integrated circuit; and a hybrid heat transfer system coupled to the integrated circuit to cool the integrated circuit during operation of the network device, the hybrid heat transfer system including: a thermosiphon heat transfer subsystem including a condenser coupled to an evaporator, the evaporator attached to the integrated circuit and positioned below the condenser relative to a direction of gravity; and a supplemental heat transfer subsystem thermally coupled to the evaporator of the thermosiphon heat transfer subsystem, the supplemental heat transfer subsystem including at least a portion extending below the evaporator relative to the direction of gravity.

In an embodiment of the network device, the supplemental heat transfer subsystem comprises one of a heat pipe heat transfer subsystem and a vapor chamber heat transfer subsystem.

In an embodiment of the network device, the network device comprises one of a network router and a network switch.

The above description illustrates various embodiments along with examples of how aspects of some embodiments may be implemented. The above examples and embodiments should not be deemed to be the only embodiments and are presented to illustrate the flexibility and advantages of some embodiments as defined by the following claims. Based on the above disclosure and the following claims, other arrangements, embodiments, implementations and equivalents may be employed without departing from the scope of the present disclosure.

What is claimed is:

1. A hybrid heat transfer system, comprising:
a thermosiphon heat transfer subsystem including a condenser coupled to an evaporator, the evaporator configured to be coupled to a heat source and positioned below the condenser relative to a direction of gravity; and
a supplemental heat transfer subsystem thermally coupled to the evaporator of the thermosiphon heat transfer subsystem, the supplemental heat transfer subsystem including at least a portion extending below the evaporator relative to the direction of gravity.

2. The hybrid heat transfer system of claim 1, wherein the supplemental heat transfer subsystem comprises a heat pipe heat transfer subsystem.

3. The hybrid heat transfer system of claim 1, wherein the supplemental heat transfer subsystem comprises a vapor chamber heat transfer subsystem.

4. The hybrid heat transfer system of claim 1, wherein the evaporator includes a first surface configured to be attached to the heat source and includes a second surface attached to the supplemental heat transfer subsystem.

5. The hybrid heat transfer system of claim 1, wherein the evaporator is thermally coupled through the supplemental heat transfer subsystem to a heat source.

6. The hybrid heat transfer system of claim 5, wherein the supplemental heat transfer subsystem includes an attachment portion thermally coupled to the first surface of the evaporator and includes a heat dissipation portion extending below the attachment portion and the evaporator relative to the direction of gravity.

7. The hybrid heat transfer system of claim 1, wherein the evaporator includes a lower surface configured to be coupled to the supplemental heat transfer subsystem extending below the evaporator relative to the direction of gravity.

8. The hybrid heat transfer system of claim 1, wherein the condenser of the thermosiphon heat transfer subsystem further comprises heat fins to dissipate heat.

9. The hybrid heat transfer system of claim 1, wherein the supplemental heat transfer subsystem further comprises heat fins to dissipate heat.

10. A hybrid heat transfer system, comprising:
a thermosiphon heat transfer subsystem including a condenser coupled to an evaporator, the evaporator having a structure to be coupled to a heat source and being positioned below the condenser along a direction of gravity; and
a supplemental heat transfer subsystem thermally coupled to the evaporator of the thermosiphon heat transfer subsystem to remove heat generated by the heat source, at least a portion of the supplemental heat transfer subsystem positioned below the evaporator along the direction of gravity.

11. The hybrid heat transfer system of claim 10, wherein the supplemental heat transfer subsystem comprises at least one of a heat pipe heat transfer subsystem or a vapor chamber heat transfer subsystem.

12. The hybrid heat transfer system of claim 10, wherein the evaporator includes a first surface to be attached to the heat source and includes a second surface opposite the first surface attached to the supplemental heat transfer subsystem.

13. The hybrid heat transfer system of claim 10, wherein the supplemental heat transfer subsystem includes an attachment portion and a heat dissipation portion, the attachment portion including a first surface attached to the evaporator and including a second surface opposite the first surface to be attached to the heat source.

14. The hybrid heat transfer system of claim 10, wherein the evaporator includes a lower surface relative to the direction of gravity and wherein the supplemental heat transfer subsystem is attached to the lower surface and is positioned entirely below the evaporator relative to the direction of gravity.

15. The hybrid heat transfer system of claim 10, wherein the condenser includes a first surface and wherein thermosiphon heat transfer subsystem further comprises at least one heat sink attached to the first surface of the condenser.

16. The hybrid heat transfer system of claim 15, wherein the condenser further includes a second surface opposite the first surface, and wherein the thermosiphon heat transfer subsystem further comprises at least one heat sink attached to the second surface of the condenser.

17. The hybrid heat transfer system of claim 16 further comprising at least one heat sink attached to the thermosiphon heat transfer subsystem.

18. A network device, comprising:
a data plane to forward network packets from an ingress port to an egress port;
a control plane to configure the data plane, the control plane including:
an integrated circuit; and
a hybrid heat transfer system coupled to the integrated circuit to cool the integrated circuit during operation of the network device, the hybrid heat transfer system including:
a thermosiphon heat transfer subsystem including a condenser coupled to an evaporator, the evaporator attached to the integrated circuit and positioned below the condenser relative to a direction of gravity; and
a supplemental heat transfer subsystem thermally coupled to the evaporator of the thermosiphon heat transfer subsystem, the supplemental heat transfer subsystem including at least a portion extending below the evaporator relative to the direction of gravity.

19. The network device of claim 18, wherein the supplemental heat transfer subsystem comprises one of a heat pipe heat transfer subsystem and a vapor chamber heat transfer subsystem.

20. The network device of claim 18, wherein the network device comprises one of a network router and a network switch.
